(19) United States
(12) Patent Application Publication
(10) Pub. No.: US 2012/0274308 A1
(43) Pub. Date: Nov. 1, 2012

(54) VOLTAGE DETECTION CIRCUIT

(75) Inventor: CHUAN-TSAI HOU, Tu-Cheng (TW)

(73) Assignee: HON HAI PRECISION INDUSTRY CO., LTD., Tu-Cheng (TW)

(21) Appl. No.: 13/153,762

(22) Filed: Jun. 6, 2011

(30) Foreign Application Priority Data
Apr. 27, 2011 (TW) 100114692

(51) Int. Cl. G01R 19/00

(52) U.S. Cl. 324/76.11

(57) ABSTRACT

A voltage detection circuit is used for determining whether a voltage of a power supply is less than a preset voltage. The circuit includes a Zener diode, a first electronic switch, a second electronic switch, and a controller. When the controller receives a high level signal, the controller warns the users that the voltage of the power supply is less than 3.3 volts.

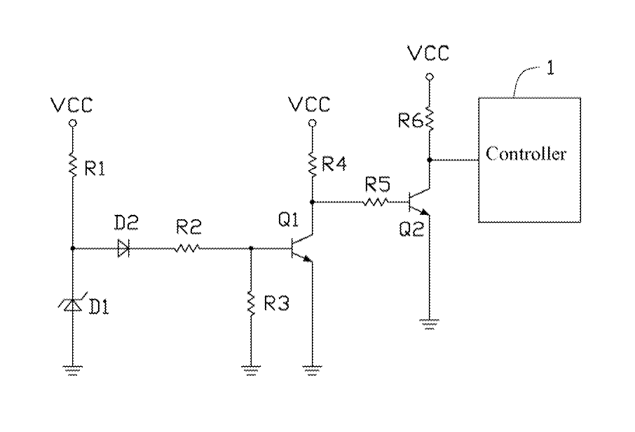

### BACKGROUND

1. Technical Field

The present disclosure relates to a detection circuit.

2. Description of Related Art

Generally, a voltage detection circuit can be used for determining whether a voltage of a power supply is less than a preset voltage. However, the voltage detection circuit usually includes comparators, which are expensive.

### BRIEF DESCRIPTION OF THE DRAWING

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

The figure is a circuit diagram of an exemplary embodiment of a voltage detection circuit.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

Referring to the figure, a voltage detection circuit is used for determining whether a voltage of a power supply VCC is less than a preset voltage. An exemplary embodiment of the voltage detection circuit includes a Zener diode D1, a diode D2, two transistors Q1 and Q2, and resistors R1-R6.

A cathode of the Zener diode D1 is connected to the power supply VCC through the resistor R1. The cathode of the Zener diode D1 is further connected to an anode of the diode D2. An anode of the Zener diode D1 is grounded. A cathode of the diode D2 is grounded through the resistors R2 and R3 in series. A node between the resistors R2 and R3 is connected to a base of the transistor Q1. An emitter of the transistor Q1 is grounded. A collector of the transistor Q1 is connected to the power supply VCC through the resistor R4. The collector of the transistor Q1 is further connected to a base of the transistor Q2 through the resistor R5. An emitter of the transistor Q2 is grounded. A collector of the transistor Q2 is connected to the power supply VCC through the resistor R6. The collector of the transistor Q2 further outputs a signal to a controller 1 (such as a microprocessor control unit).

According to the characteristic of the Zener diode, the Zener diode D1 and the resistor R1 can be used to make a simple voltage regulator circuit. The voltage regulator circuit enables a fixed stable voltage to be taken from an unstable voltage source such as the power supply VCC. When a voltage of the Zener diode D1 is greater than or equal to a reverse breakdown voltage, the voltage regulator circuit outputs the fixed stable voltage. When the voltage of the Zener diode D1 is less than the reverse breakdown voltage, the voltage regulator circuit does not work. As a result, in the embodiment, when the power supply VCC is less than 3.3 volts (V), the voltage regulator circuit cannot output the fixed stable voltage. When the power supply VCC is greater than or equal to 3.3V, the voltage regulator circuit outputs the fixed stable voltage.

When the power supply VCC is greater than or equal to 3.3V, a voltage at the cathode of the Zener diode D1 is approximately 3.3V. As a result, a voltage at the cathode of the diode D2 is 2.6V. Moreover, if the voltage at the base of the transistor Q1 is Vb, then using the voltage divider formula, we have: Vb=2.6*R3/(R2+R3). In this embodiment, the resistances of the resistors R2 and R3 are set to make the voltage at the base of the transistor Q1 equals to 0.7V. In other words, the function of Vb=2.6*R3/(R2+R3)=0.7V is satisfied.

In this condition, according to the characteristic of the transistor, the transistor Q1 is turned on. The transistor Q2 is turned off. As a result, the controller 1 receives a high level signal. The controller 1 does not warn users.

When the voltage of the power supply VCC is less than 3.3V, a voltage output from the Zener diode D1 is less than 3.3V. At this time, the function of Vb=2.6*R3/(R2+R3)<0.7V is satisfied. The transistor Q1 is turned off. The transistor Q2 is turned on. As a result, the controller 1 receives a low level signal, thus warning the users that the voltage of the power supply VCC is less than 3.3V.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A voltage detection circuit for a power supply, the circuit comprising:
a Zener diode comprising a cathode connected to the power supply through a first resistor, and an anode grounded, wherein the cathode of the Zener diode is further connected to a first terminal of a second resistor, a second terminal of the second resistor is grounded through a third resistor;
a first electronic switch comprising a first terminal connected to a node between the second and third resistors, a second terminal grounded, and a third terminal connected to the power supply through a fourth resistor;
a second electronic switch comprising a first terminal connected to the third terminal of the first electronic switch through a fifth resistor, a second terminal grounded, and a third terminal connected to the power supply through a sixth resistor; and
a controller connected to the third terminal of the second electronic switch to receive a signal, wherein the controller determines whether a voltage of the power supply is less than a preset voltage according to the signal.

2. The circuit of claim 1, wherein the first electronic switch is a transistor, a base of the transistor is the first terminal of the first electronic switch, an emitter of the transistor is the second terminal of the first electronic switch, a collector of the transistor is the third terminal of the first electronic switch.

3. The circuit of claim 1, wherein the second electronic switch is a transistor, a base of the transistor is the first terminal of the second electronic switch, an emitter of the transistor is the second terminal of the second electronic switch, a collector of the transistor is the third terminal of the second electronic switch.

4. The circuit of claim 1, further comprising a diode, wherein an anode of the diode is connected to the cathode of the Zener diode, a cathode of the diode is connected to the second resistor.
